(19) United States
(12) Patent Application Publication
(10) Pub. No.: US 2023/0217803 A1
(43) Pub. Date: Jul. 6, 2023

(54) ELECTRONIC DEVICE MATERIAL, ELECTRONIC DEVICE, SENSOR DEVICE, AND GAS SENSOR

(71) Applicant: Toray Industries, Inc., Tokyo (JP)

(72) Inventors: Yoshitake Masuda, Nagoya-shi, Aichi (JP); Takafumi Akamatsu, Nagoya-shi, Aichi (JP); Akihiro Tsuruta, Nagoya-shi, Aichi (JP); Takayoshi Hirai, Otsu-shi, Shiga (JP); Kojiro Naito, Otsu-shi, Shiga (JP); Seiichiro Murase, Otsu-shi, Shiga (JP)

(73) Assignee: Toray Industries, Inc., Tokyo (JP)

(21) Appl. No.: 18/008,501

(22) PCT Filed: Jun. 10, 2021
(86) PCT No.: PCT/JP2021/022188

§ 371 Date: Dec. 6, 2022

(30) Foreign Application Priority Data
Jun. 15, 2020 (JP) 2020-103337
Mar. 26, 2021 (JP) 2021-054191

(51) Int. Cl. H10K 85/20; G01N 27/12

(52) U.S. Cl. CPC H10K 85/225; G01N 27/127; B82Y 15/00

(57) ABSTRACT

An electronic device material includes: carbon nanotubes having a purity of Semiconductor Carbon Nanotubes of 80% by mass or more; and a n-type semiconductor.

### CROSS REFERENCE TO RELATED APPLICATIONS

This application is the U.S. National Phase application of PCT/JP2021/022188, filed Jun. 10, 2021, which claims priority to Japanese Patent Application No. 2020-103337, filed Jun. 15, 2020 and to Japanese Patent Application No. 2021-054191, filed Mar. 26, 2021, the disclosures of these applications being incorporated herein by reference in their entireties for all purposes.

### FIELD OF THE INVENTION

The present invention relates to an electronic device material, an electronic device, a sensor device, and a gas sensor. More specifically, the present invention relates to a gas sensor including Semiconductor Carbon Nanotubes.

### BACKGROUND OF THE INVENTION

In recent years, from increased requirement for environmental problems represented by global warming, food safety, and health consciousness, technologies for detecting trace amounts of chemical substances (sensors) have been expected to achieve various developments such as detection of volatile organic compounds (VOCs) in the air, control of freshness during food distribution, control and diagnosis of physical conditions by detecting skin gases or the like emitted from the human body, improvement in comfortability in spaces used by a plurality of users such as airplanes, trains, and automobiles by detecting odors, reduction in the burden on caregivers and improvement in the QOL of care-recipients by detecting gases derived from excrement, and improvement in security by detecting hazardous gases.

In particular in healthcare fields, where demands have been significantly increasing, the sensors have been attracting attention in recent years because gases included in exhaled breath include many relatively simple substances and are easily analyzed, and thus the sensors are conveniently used for disease detection and physical condition management through simple testing.

The demand of the technologies of gas sensors, which are required for high sensitivity and selective detection of gases in real time, has particularly increased. In addition, high detection sensitivity on the order of ppb and selective detection capability from a wide variety of gases have been required for the sensors not only in the healthcare field but also in many other fields where demand has been increasing.

However, the major commercially available gas sensors have detection sensitivity on the order of ppm, which is insufficient sensitivity. The sensors also have problems of large power consumption due to high operating temperatures (200° C. to 500° C.) as well as rapid deterioration and little identification ability of the kinds of gases, resulting in incapability of responding to the demand. In reality, therefore, in order to respond to the demand, an apparatus in which a special analyzer specialized in one field used in laboratories and other facilities is incorporated or combined is used instead of sensors in any cases. Such an equipment is extremely expensive and not versatile and thus the equipment can respond to only significantly limited demands.

In order to address the insufficient detection sensitivity of the gas sensors, a method for improving sensitivity by more easily detecting the trace amount of molecules due to an effect of increasing a surface area by forming materials used in the sensors into nanosize material (Non Patent Literature 1) and a method for improving the sensitivity through signal intensity amplification due to hybridization in which a plurality of materials are combined (Non Patent Literature 2) have been studied.

In addition, in order to address the high consumption power and the degradation due to the high operating temperature (200° C. to 500° C.), development studies in which both low temperature drive and high sensitivity are satisfied by using nanocarbon materials have been performed (Patent Literature 1).

Furthermore, it has been reported that the use of nanocarbon materials having high semiconductor purity allows the sensitivity to be improved more (Non Patent Literature 3).

On the other hand, any of many gas sensors that are currently used in general detect all gas molecules causing oxidation reaction because such sensors utilize mechanism of detecting electric change on a surface at the time of reaction of oxygen at the surface of a metal oxide compound with the gas molecules at high temperature (200° C. to 500° C.) Consequently, such sensors have no gas selectivity except a part of gases such as carbon dioxide.

At present, therefore, gases are selected by controlling the reactivity of the surface of detection parts by controlling the temperature of a heater, eliminating gases that are not the targets of the detection using a filter, and analyzing waveforms by attaching an apparatus that reads detection waveforms outside the sensors. However, it is difficult to provide selectivity for a wide variety of gases because merely two or three kinds of selectivity that can be largely divided into two categories such as gas combustion temperature and gas molecular diameter are combined.

Therefore, it is a difficult state to apply the sensors to applications for many foreign gases such as the healthcare field, in which demand is expected to increase most. In addition, ingenuity such as a combination of a plurality of types of filters is technically possible. However, such ingenuity is not realistic because the ingenuity leads to deterioration in the detection sensitivity and higher costs.

### PATENT LITERATURE

Patent Literature 1: Japanese Patent Application Laid-open No. 2008-185495

### Non Patent Literature

Non Patent Literature 1: ACS Omega. 3, pp. 14592-14596 (2018)

Non Patent Literature 2: Sens. Actuat. B170p, 67-74 (2012)

Non Patent Literature 3: ASC Sens. 3, 79-86 (2018)

### SUMMARY OF THE INVENTION

With respect to the materials for electronic devices that become increasingly important in the field of sensing devices of which demand increases, few kinds of materials that selectively identify substances exist. In particular for the materials for the sensors, because few kinds of device materials having substance (molecule) selectivity functions exist in the materials for electronic devices themselves, the materials for the sensors tend to have narrow selectivity to substances when the materials for the sensors are provided with the selectivity by combining with peripheral devices.

In addition, none of the methods described in Patent Literature 1 or Non Patent Literatures 1 to 3 can solve the problem of the materials for gas sensing used in commercially available sensors, which have almost no identification ability of gases.

An object of the present invention is to provide a material for devices that can selectively identify chemical substances. In particular, in the field of the gas sensors, an object of the present invention is to provide an electronic device material, an electronic device, a sensor device, and a gas sensor that can be used as a gas-sensitive element having low temperature drive, high sensitivity, and selective detection ability for gas molecules.

Namely, the present inventions are as follows.

(1) An electronic device material including: carbon nanotubes having a purity of Semiconductor Carbon Nanotubes of 80% by mass or more; and a n-type semiconductor.
(2) The electronic device material according to (1), in which the carbon nanotubes are a carbon nanotube composite with a polymer attached to at least a part of surfaces of the carbon nanotubes.
(3) The electronic device material according to (2), in which the polymer is a semiconducting polymer.
(4) The electronic device material according to any one of (1) to (3), in which the n-type semiconductor has a nanostructure.
(5) The electronic device material according to any one of (1) to (4), in which the n-type semiconductor is an oxide semiconductor.
(6) The electronic device material according to any one of (1) to (5), in which the electronic device material is a gas-sensitive element.
(7) An electronic device including the electronic device material according to any one of (1) to (6).
(8) A sensor device including the electronic device material according to any one of (1) to (6).
(9) A gas sensor including the sensor device according to (8).

The electronic device material according to the present invention can be used as a gas-sensitive element having low-temperature drive, high sensitivity, and gas identification ability.

### BRIEF DESCRIPTION OF DRAWINGS

FIG. 1 is a schematic diagram illustrating a sensor device according to an embodiment of the present invention.

FIG. 2 is a view illustrating gas detection with the sensor device according to the embodiment of the present invention.

FIG. 3 is a view illustrating the result of ammonia detection with the sensor device according to the embodiment of the present invention.

FIG. 4 is a view illustrating the result of nitric oxide detection with the sensor device according to the embodiment of the present invention.

FIG. 5 is a view illustrating the result of ammonia detection with the sensor device according to Comparative Example.

FIG. 6 is a view illustrating the result of nitric oxide detection with the sensor device according to Comparative Example.

FIG. 7 is a view illustrated in the form of a graph for comparing the detection results of ammonia and nitric oxide with the sensor device according to the embodiment of the present invention.

FIG. 8 is a view illustrated in the form of a graph for comparing the detection results of ammonia, methane, toluene, cyclohexane, and nitric oxide with the sensor device according to the embodiment of the present invention.

FIG. 9 is a view illustrated in the form of a graph for comparing the detection results of ammonia and nitric oxide with the sensor device according to Comparative Example.

FIG. 10 is a view illustrated in the form of a graph for comparing the detection results of ammonia and nitric oxide with the sensor device according to Comparative Example.

FIG. 11 is a view illustrated in the form of a graph for comparing the detection results of ammonia, methane, toluene, cyclohexane, and nitric oxide with the sensor device according to the embodiment of the present invention.

### DETAILED DESCRIPTION OF EMBODIMENTS OF THE INVENTION

Hereinafter, a suitable embodiment of the electronic device material including CNT having a purity of Semiconductor Carbon Nanotubes (hereinafter referred to as “CNTs”) of 80% by mass or more and a n-type semiconductor will be described in detail. However, the present invention is not limited to the following embodiments but can be implemented with various modifications depending on the purposes and applications.

First, an electronic device material made of CNTs having a purity of the Semiconductor Carbon Nanotubes of 80% by mass or more and the n-type semiconductor will be described. Herein, the purity of the Semiconductor Carbon Nanotubes of 80% by mass or more means that the ratio of the Semiconductor Carbon Nanotubes in the total CNTs is 80% by mass or more. CNTs are usually a mixture of Semiconductor Carbon Nanotubes and metallic carbon nanotubes in a mass ratio of 2:1 and thus the purity of the Semiconductor Carbon Nanotubes in CNTs is 66.7% by mass. For the Semiconductor Carbon Nanotubes, a threshold value between a condition under which current flows and a condition under which current does not flow exists depending on the voltage applied to a device. In contrast, no delimitation exists for the metallic carbon nanotubes. Therefore, a high ratio of the metallic carbon nanotubes results in easily generating pathways connected between the metallic carbon nanotubes in the network of CNTs connecting between electrodes, and thus the on/off delimitation of the current becomes unclear. As a result, as the electronic devices, the switchover of switching and the delimitation of signal detection (a boundary between signals and noise) become unclear. In the case where such CNTs are used in the sensor devices, the use leads to noises increase and deterioration in sensitivity. As the purity of the Semiconductor Carbon Nanotubes become higher, the switching and the signal detection become more advantageous and thus as the purity of the Semiconductor Carbon Nanotubes becomes higher, the Semiconductor Carbon Nanotubes become better. As described below, higher purity of the semiconductor is better in terms of the selectivity of detected molecules. The CNTs used in the present invention are required to have a purity of the Semiconductor Carbon Nanotubes of 80% by mass or more. The purity is more preferably 85% by mass or more, further preferably 90% by mass or more, and most preferably 95% by mass or more.

As one aspect, the CNTs required in the present invention and having a purity of the Semiconductor Carbon Nanotubes of 80% by mass or more exhibit an effect as the sensor devices. Compositing the CNTs having a purity of the Semiconductor Carbon Nanotubes of 80% by mass or more with the n-type semiconductor allows different selectivity to external substances from the material alone to be exhibited as the material for sensor devices.

The principle of generating the different selectivity is not clear. Under a normal atmospheric state, the Semiconductor Carbon Nanotubes are a material that exhibits the characteristics of a p-type semiconductor, in which holes act as carriers for electricity. Therefore, the electronic device material exhibits diode-like rectification properties by compositing so that the electronic device material has a junction part with the n-type semiconductor. Alternatively, it is presumed that such CNTs become hole-rich by compositing, deviation of the electron state is generated so that n-type semiconductors become electron-rich, and thus the composited product has electron donating and accepting ability that is different from the case of respective independent p-type and n-type semiconductors. Therefore, it is presumed that selectivity in electron transfer to the contacted or attached chemical substances to the composite material part is generated.

For example, in the case where the external chemical substances are gas molecules, gases in which electron transfer occurs and gases in which electron transfer does not occur depending on the oxidizing power or reducing power of the gas molecules. Therefore, the use of the electronic device material according to the present invention as the material for sensor devices allows the electronic device material to be used as gas sensors having the selectivity in the response properties of the gases. The electronic device material can be used as the material for sensor devices for all chemical substances because the selectivity is generated not only for gases but also for liquids depending on the oxidizing power or reducing power of the chemical substances constituting the liquid.

It is conceivable that the selectivity of the external substances is characteristics generated by the rectification properties of the contact part (junction part) between the p-type semiconductor and the n-type semiconductor or electric charge deviation generated by the contact between the p-type semiconductor and the n-type semiconductor. Mixing in high concentration of the metallic carbon nanotubes not having the semiconductor properties causes the p-type semiconductor properties as whole CNTs to decrease and thus the effect to decrease (noise component increases due to leakage current of the metallic carbon nanotubes and, at the same time, the rectification properties or the deviation of the electric charge decrease). Therefore, as described in Non Patent Literature 2, no selectivity is particularly observed in the response properties to the external chemical substances such as gases for the composite product of common CNTs having a purity of Semiconductor Carbon Nanotubes of 66.7% by mass and the n-type semiconductor, in which the purity of the Semiconductor Carbon Nanotubes is not particularly increased.

The purity of the Semiconductor Carbon Nanotubes required for the CNTs used in the present invention depends on the aspect of applications to the electronic devices. The CNTs having a purity of the Semiconductor Carbon Nanotubes of 80% by mass or more allow the selectivity to the chemical substances to be obtained as the composite material. CNTs having a purity of the Semiconductor Carbon Nanotubes of 90% by mass or more allow the selectivity to be obvious and CNTs having a purity of the Semiconductor Carbon Nanotubes of 95% by mass or more allow no noise to be realistically observed, which is preferable. In the case where the electronic device material according to the present invention is used as the material for sensor devices, signal change becomes clearer and is more easily read, as the leakage current when voltage is off becomes smaller, in signals indicated by the difference between current when the voltage is on and current when the voltage is off (leakage current, that is, noise).

Consequently, even small signals can be read. It is preferable that the ratio of the current when the voltage is on and off becomes clearer. However, the metallic carbon nanotubes easily conduct current and thus the amount of the metallic carbon nanotubes becomes larger, the leakage current when the voltage is off becomes larger. Consequently, the current difference between on and off is more difficult to read and thus the performance as the sensor is more difficult to improve. In other words, the sensitivity as a sensor is not improved. Conversely, as the purity of the Semiconductor Carbon Nanotubes becomes higher, the leakage current when the voltage is off becomes smaller and less noise is generated, so that the signal is easily read, the sensitivity of the sensor becomes high, and the selectivity is clearly exhibited.

In the case where a sensor device having high sensitivity is required, a higher purity of the Semiconductor Carbon Nanotubes in the CNTs provides a preferable aspect. CNTs having a purity of the Semiconductor Carbon Nanotubes of 80% by mass or more allow parts where the metallic carbon nanotubes alone are three-dimensionally connected to rarely exist when the CNTs are used as electrodes, and CNTs having a purity of the Semiconductor Carbon Nanotubes of 90% by mass or more allow the metallic carbon nanotubes to be more easily isolated. Consequently, the leakage current is difficult to flow and thus a sensor device having high sensitivity and high selectivity is provided. CNTs having a purity of the Semiconductor Carbon Nanotubes of 95% by mass or more are the best because the influence of the metallic carbon nanotubes is realistically extremely small.

The electronic device material according to the present invention can be used as the material for sensor devices and is particularly useful when the electronic device material is used as the material for gas sensors. The electronic device material according to the present invention can be applied as sensor devices that do not require heating because the electronic device material can utilize a phenomenon in which change in a resistance value (change in current) occurs simply by the contacting of the gas with or the adhering of the gas to the CNTs. In addition, use of the CNTs having a substantially large surface area due to the nanomaterial properties allows the electronic device material to be used as a highly sensitive gas sensor having a large contact area to gas and thus the electronic device material can be used as the material for sensors having selectivity to chemical substance species without using external apparatuses.

Because the electronic device material according to the present invention can utilize the above large surface area property of the CNTs, trace amounts of chemical substances can be detected on the order of ppm and can be detected on the order of ppb and even on the order of ppt under appropriate conditions. For example, chemical substances can be detected on the order of ppt by connection of a measurement apparatus such as a digital multimeter capable of detecting current changes on the order of nanoamperes and by measurement of the current change. As the semiconductor purity of the CNTs becomes higher, the trace amounts of chemical substances can be more easily detected. The semiconductor purity is not limited as long as the detection target substances are on the order ppm. However, in the case where detection on the order of ppb is required, the semiconductor purity is preferably 80% by mass or more and in the case where detection on the order of ppt is required, the semiconductor purity is preferably 90% by mass or more. The electronic device material having a semiconductor purity of 95% by mass or more allows trace chemical substances having a concentration of 100 ppt or less to be detected.

As the methods for achieving a purity of the Semiconductor Carbon Nanotubes in CNTs of 80% by mass or more, known methods can be used. Examples of the known methods include a method for increasing the purity by ultracentrifugation in the co-existence with a density gradient techniques, a method for selectively attaching a specific compound to the surface of the Semiconductor Carbon Nanotubes or the metallic carbon nanotubes and separating the Semiconductor Carbon Nanotubes and the metallic carbon nanotubes by utilizing differences in solubility, and a method for increasing the purity of the Semiconductor Carbon Nanotubes by electrophoresis utilizing difference of electric properties. Examples of methods for measuring the content of the Semiconductor Carbon Nanotubes in CNTs include a method for calculating from the absorption area ratio of a visible-to-near-infrared absorption spectrum and a method for calculating from the intensity ratio of a Raman spectrum.

As described above, the electronic device material according to the present invention can selectively detect the trace amounts of chemical substances by combining the CNTs having increased semiconductor purity and the n-type semiconductor. For example, in the case of the electronic device material formed by combining the CNTs having increased semiconductor purity and tin oxide (SnO₂) serving as the n-type semiconductor, the electronic device material indicates high-sensitive response properties for reducing compounds and indicates low-sensitive response properties or no response properties for oxidative compounds, resulting in enabling the reducing chemical compounds and the oxidizing chemical compounds to be identified.

At this time, examples of the oxidizing chemical compounds include nitric oxide, nitrogen dioxide, nitric acid, nitrous acid, chloric acid, perchloric acid, hypochlorous acid, sulfur monoxide, sulfur dioxide, sulfur peroxide, ozone, hydrogen peroxide, halogens such as fluorine, chlorine, bromine, and iodine, and gases such as hydrogen fluoride, hydrogen chloride, and hydrogen bromide. Examples of the reducing chemical compounds include ammonia, hydrogen, and carbon monoxide. Examples of chemical compounds indicating weakly reducing properties include aldehydes such as formaldehyde and acetaldehyde, alcohols such as methanol and ethanol, organic compounds having n electrons such as alkynes including acetylene, alkenes including ethylene, and aromatic compounds including toluene.

In addition, the electronic device material according to the present invention formed by combining the n-type semiconductor such as tin oxide (SnO₂) and the CNTs having increased semiconductor purity indicates excellent response properties to near neutral chemical substances such as alkanes including methane, ethane, and cyclohexane and carbon dioxide. These characteristics that can detect even weakly reducing compounds and near-neutral chemical compounds are considered to be generated by the use of the CNTs that cause electrical fluctuations depending on the attached amount of chemical substances simply by the adhering of the chemical substances, as generally described in known literatures. (It is conceivable that the CNTs convert changes in the surrounding environment into electrical behaviors.) Therefore, the electronic device material exhibits electrical response properties to chemical substances that do not transfer electrons through complete oxidation or reduction without causing chemical reactions.

In addition, using these properties of the CNTs and adjusting the work function of the CNTs in the composite with the n-type semiconductor also allow the selectivity threshold values to be adjusted and finer selectivity for the chemical substances (selectivity between compounds that exhibit reducing properties and selectivity between compounds that exhibit oxidizing properties) to be provided.

Examples of methods for adjusting the work function of the CNTs include a method for adjusting the work function by changing the kind of the substance that are previously in contact with the CNTs as a part of the materials for the electronic devices. The way of performing the adjustment that provides the most significant effect is to change the kind of the n-type semiconductor. The method of changing the kind of the n-type semiconductor is used at the time of significantly adjusting the work function of the CNTs. In the case where the work function of the CNTs is controlled in detail, a method for previously wrapping the CNTs with a semiconducting polymer and changing the kind of the polymer used for wrapping is exemplified. This method allows the work function to be finely adjusted. In addition, examples of the method for change the selectivity threshold value in further detail include a method for changing environmental temperature at which the electronic device material is used. It is presumed that this change is caused by changing the probability of the existence of free electrons existing in the conductive band of the CNTs by changing the temperature.

In the electronic device material according to the present invention, the CNTs are preferably a CNT/polymer composite with a polymer attached to at least a part of the surfaces of the CNTs. Herein, the polymer is a compound in which the repeating unit has a conjugated structure and the degree of polymerization is 2 or more. Compositing the CNTs with the polymer is preferable in that this prevents bundling of the CNTs and allows the surface area of the CNTs to be effectively used.

As the polymer, use of the semiconducting polymer is a more preferable aspect in terms of improving selectivity accuracy.

Compositing the CNTs with the semiconducting polymer allows the work function in which the CNT/semiconducting polymer composite is regarded as the p-type semiconductor to be adjusted. Therefore, compositing the CNTs with the semiconducting polymer allows the materials having more effective substance selectivity accuracy to be prepared. The semiconducting polymer is not particularly limited. As the most preferable aspect for compositing, compositing by using the semiconducting polymer serving as a dispersing agent for the CNTs allows an ink in which the CNTs are uniformly dispersed to be prepared and mixing the CNTs with the n-type semiconductor using the ink in which the CNTs are uniformly dispersed allows a state in which the CNTs are homogeneously closely attached to the n-type semiconductor to be easily formed, which is preferable.

In the case where the semiconducting polymer cannot be used as the dispersing agent, the effect of the CNT/semiconducting polymer composite can be obtained by only mixing the CNTs with a solution in which the semiconducting polymer is dissolved in a solvent that dissolves the semiconducting polymer and thereafter using a mixture in the form of a suspension or paste formed by a method for mixing by kneading or the like. From the viewpoint of reducing detection noise when the electronic device material is used as the sensor devices, the suspension or the paste including the semiconducting polymer and the CNTs is preferably uniformly mixed.

The amount of the semiconducting polymer relative to the CNTs is preferably used about 10 times or less in a mass ratio and is preferably used 3 times or less in the using method in which the semiconducting polymer also has a role of the dispersing agent because an excessive used amount of the semiconducting polymer results in burying the CNTs into the semiconducting polymer and the characteristics as the material become the characteristics of the semiconducting polymer. In addition, in the case where the influence of the characteristics of the semiconducting polymer itself is avoided as much as possible, the semiconducting polymer that is not attached to the CNTs is preferably removed by classification, washing, or other means.

In terms of not interfering with the semiconductor characteristics of the CNTs, the semiconducting polymers described in, for example, Japanese Patent No. 5470763 and Japanese Patent No. 5454139 can be suitably used as the particularly preferably semiconducting polymers because these polymers can also be used together as the dispersing agent for the CNTs. Semiconducting polymers that can be purchased such as poly[(9,9-di-n-octylfluorenyl-2,7-diyl)-alt-(benzo[2,1,3 thiadiazole-4,8-diyl)] (F8BT) and poly(3-hexylthiophene) (P3HT) can be appropriately used.

In the present invention, appropriately combining

CNTs serving as the p-type semiconductor and having a purity of the Semiconductor Carbon Nanotubes of 80% by mass or more and the n-type semiconductor to form a composite material allows the electronic device material having the selectivity ability for contacted or attached external substances to be prepared. It is conceivable that the electronic device material according to the present invention causes the selectivity to the chemical substances due to the diode-like rectification effect or the deviation of the electric charge at the junction surface part of the p-type semiconductor (CNTs) and the n-type semiconductor. Therefore, the electronic device material according to the present invention provides clearer selectivity as the composite material is formed so that the contact area between the CNTs and the n-type semiconductors is increased more. The method for mixing is not particularly limited as long as the contact area is increased. Forming the CNTs into the ink and thereafter applying or mixing to the n-type semiconductor and drying tends to form a state where the CNTs closely attached to the n-type semiconductor, which is preferable.

In the present invention, forming a state where the CNTs are in contact with the n-type semiconductor results in a state where the electric charge is deviated on the CNTs as a state of the electric charge on the CNTs as compared to the case of the CNTs alone due to the influence of the contacted n-type semiconductor. As a result, the excess electric charge provides the advantage of improving response speed as compared to the CNTs alone. This also allows the materials for the electronic devices according to the present invention to be used as the material for sensors having higher sensitivity than the case where the CNTs or the n-type semiconductor is used alone. A S/N ratio, which is the ratio of signal (S) to noise (N), can be S/N=3 to 500 even when trace amount of chemical substances on the order of ppb are detected. S/N=3 to 300 is possible even in the case where the trace amounts of the chemical substances are detected on the order of ppt.

The structure of the n-type semiconductor in order to obtain the effect of the electronic device material according to the present invention is not particularly limited. A nanostructure is a preferable structure when the n-type semiconductor is used as the material for sensor devices because the nanostructure provides the effect of improved sensitivity due to a larger surface area. The nanostructure described herein is an aggregate of particles, sheets, crystals, and the like having one or more of the dimensions of a length, a width, and a height on the nanoscale (1.0 nm to 999.9 nm) or an aggregate of pores having a dimension of nanoscale. Examples of the structures of the nanostructure include one or more structures selected from the group consisting of metal-organic structures (MOF, Metal-Organic Frameworks), zeolites, mesoporous products, mesoporous materials, macroporous porous products, layered compounds, clay minerals, metal complexes, porous organosilica hybrid materials, ionic crystals, nanosheet liquid crystals, colloidal template materials, and colloidal crystals. The nanostructure can be confirmed by performing cross-sectional analysis of the constituent part of the material using electron microscopy (transmission electron microscopy or scanning electron microscopy) and measuring the length, width, and height of the particles, sheets, crystals, or pores. In the case where the electronic device material is used as the material for sensors, clearness of the signal intensity to noise is also required in many cases. Although sufficient signal intensity is obtained by only simply mixing so that the CNTs and the n-type semiconductor have junction parts, the n-type semiconductor is preferably a nanostructure as an excellent aspect for obtaining more sufficient signal intensity as the sensor devices. As the CNTs serving as the p-type semiconductor have the nanostructure, the CNTs have a high specific surface area and thus the necessary signal intensity can be obtained even when the n-type semiconductor does not have the nanostructure. Due to both of the p-type semiconductor and the n-type semiconductor having the nanostructures, the signal-to-noise ratio tends to become clear because the signal intensity increases due to a larger specific surface area as the material for sensors and a larger contact area to the external substances.

In addition, it is conceivable that the current value is larger than that of common diodes and the effect of improving detection sensitivity due to signal intensity amplification is likely to be obtained by the effect of a short-diode constitution in which electrodes are closer than the diffusion length of diffusion current from the p/n junction surface in both of the p-type semiconductor and n-type semiconductor due to forming the n-type semiconductor into the nanostructure.

In the electronic device material according to the present invention, the n-type semiconductor used in combination with the CNTs having a purity of the Semiconductor Carbon Nanotubes of 80% by mass or more provides the effect of the detection selectivity of the chemical substances of the present invention regardless of the kind of the n-type semiconductor. Changing the kind of the n-type semiconductor allows the value of the work function of the n-type semiconductor to be adjusted and thus the selectivity of the molecular species in contact with the electronic device material according to the present invention can also be adjusted when the n-type semiconductor is used as the sensor.

As the n-type semiconductor, an oxide semiconductor is suitably used. The oxide semiconductor is preferable in that the aggregate product of the nanocrystals is easily prepared by crystal growth and is also preferable in that the nanocrystal structure can be prepared without using huge equipment. As the oxide semiconductor, tin oxide, titanium oxide, indium oxide, ITO, lead oxide, zinc oxide, tungsten oxide, and other oxides may be used.

The CNTs used in the electronic device material are not particularly limited as long as the CNTs have a purity of the Semiconductor Carbon Nanotubes of 80% by mass or more. As the diameter of the CNTs becomes finer, the substantial surface area becomes larger and the contact area with the gas is more increased, which is preferable. CNTs having excessively thick diameter cause the shape of the CNTs to be distorted under its own weight, resulting in changing the semiconductor properties and thus changing the material properties as the composite material. The diameter of CNTs is preferably 3.0 nm or less, more preferably 2.0 nm or less, and further preferably 1.5 nm or less. In the case of excessively thin diameter, the shape cannot be retained. The lower limit at which a tubular shape is retained is 0.4 nm and the practical lower limit that can be produced at the current industrial level is 0.7 nm.

As the length of the CNTs becomes longer, the CNTs become more preferable. Examples of the reason include that the resistance part at the contact point is decreased in the network structure between the CNTs connecting electrodes. This allows the conductivity as a CNT film to be improved and the response properties to be excellent. As the length of the CNTs becomes longer, the CNTs become more preferable from the viewpoint of the conductivity of the CNT network. However, excessively long CNTs tend to form a ring state so that one CNT coils up or a serpentining state. In addition, these CNTs also tend to bundle together, resulting in not effectively utilizing the high surface area properties and ballistic electric conductivity of the CNTs. Therefore, excessively long CNTs cause the response properties and selectivity at the time of forming into devices to deteriorate. The upper limit of the length of CNTs that can realistically be handled without impairing the properties of the CNTs is 10 μm at most and a range of 0.3 nm to 10.0 μm is preferable length. More preferable length is 0.4 nm to 5.0 μm and most preferable length is 0.5 nm to 3.0 μm.

In addition, utilizing CNTs also allows the trace amount of the chemical substances to be detected even in a temperature region where oxide semiconductors, which are generally distributed as products, have difficulty. Because the CNTs exhibit electric response properties when only the trace amounts of the chemical substances are attached and thus the electronic device material according to the present invention exhibits the response properties below freezing temperature (−80° C.) to 0° C. As the upper limit of usable temperature, the CNTs can be used up to the temperature at which CNTs do not burn. In the case where the CNTs are used in air atmosphere, the CNTs can be used up to 500° C. However, the detection sensitivity deteriorates in the high-temperature range due to the effects of thermal oscillations. The lower limit is not particularly limited as long as the influence of condensation or freezing does not exist.

However, when the CNTs are used in air, the CNTs are preferably used in 0° C. or more in order to avoid the effect of surface condensation. Therefore, a temperature range that exhibits excellent detection sensitivity in air and can be used generally is 0° C. to 200° C. or less. From the viewpoint of easily forming devices and using, the electronic device material can be used with excellent sensitivity in 0° C. to 100° C.

In the case where the electronic device material according to the present invention is used as the material for sensors for detecting chemical substances, repeating properties are excellent because the electrical signal change can be read by only attaching and detaching the chemical substances. The temperature range in which the repeating properties are excellent is required to be varied depending on what is detected because the adsorption power to the CNTs varies depending on the chemical substances to be detected. The excellent repeating properties are exhibited mainly in a temperature range of 0° C. to 200° C. or less.

The applications of the electronic device material are not particularly limited and is preferably used as the material for sensors. The electronic device material is preferably a gas-sensitive element. The use of the electronic device material for the material for sensors, the sensor device, and the gas sensor is preferable because the material itself has gas selectivity and thus the gas selection function that relies on peripheral devices can be omitted, which is preferable in that this leads to improvement in productivity. Utilizing CNTs also allows low-power-consumption sensors to be developed. In addition, forming the n-type semiconductors into the nanostructure allows nanosize of the material to be formed and thus a sensor having a smaller size can be formed.

The electronic device material according to the present invention also allows the p-type semiconductor material and the n-type semiconductor material to be combined without the need for huge facilities such as clean rooms and thus the sensor production process can be significantly simplified. For example, the sensor devices can be produced by printing each of the CNT ink and the tin oxide nanocrystalline ink on a substrate.

In the case where the electronic device material is used as the material for sensors, the material can be used for detecting the chemical substances even in an environment with 0% oxygen because the mere attachment of the chemical substances to the CNTs generates the electric change depending on the attached amount. A constant oxygen concentration in the environment allows the material to be used even in a range of more than 0% and 50% or less, regardless of the oxygen concentration.

At the time of using the material the electronic devices as the sensor devices, the used substrate is not particularly limited. Glass, quartz, silicon with an oxide coated film, a metal oxide, a sintered ceramic, a resin film, and the like are used.

In the case where the electronic device material according to the present invention is used as the sensor devices, a basic structure is defined by attaching metal electrodes to the electronic device material according to the present invention and conventionally known metal electrodes can be used as the metal electrodes as they are. Examples of such metal electrodes include metal electrode made of gold, platinum, silver, aluminum, nickel, chromium, and copper.

Spacing between the metal electrodes at the time of using the electronic device material according to the present invention as the sensor devices is not limited as long as the sensor devices may be large. However, as the spacing becomes narrower, the device can be formed in a smaller size. From this viewpoint, the narrower spacing is preferable. Use of the electronic device material according to the present invention allows the devices having an electrode spacing of 0.1 μm to 1000 μm to be prepared. The devices having an electrode spacing of 0.1 μm to 100 μm in a preferable aspect, 0.1 μm to 10 μm in a more preferable aspect, and 0.1 μm to 5 μm in a further preferable aspect can be prepared. As the electrode spacing becomes narrower, introduced noise becomes less and thus the devices are suitable for higher sensitive sensor devices and gas sensors (detection of the trace amounts of chemical substances). The shape of the electrodes is preferably a comb shape in order to increase the detection sensitivity.

### EXAMPLES

Hereinafter, the present invention will be described more specifically with reference to Examples. The invention, however, is not limited to Examples described below.

### EXAMPLES

### (Preparation of CNT/Semiconducting Polymer Composite Dispersion Liquid)

In order to prepare CNT/semiconducting polymer composite dispersion liquids used in Example 1, Example 2, and Comparative Example 1, first, solutions of Semiconductor Carbon Nanotubes having purities of the Semiconductor Carbon Nanotubes of 90% by mass and 94% by mass were prepared from CNTs manufactured by NoPo Nanotechnologies India Private Limited using the method described in Japanese Patent Application Laid-open No. 2012-36041.

The prepared aqueous Semiconductor Carbon Nanotube solution was filtered by a filter paper having a pore size of 0.1 μm. The filtered residue washed with about 200 mL of methanol on the filter paper, and subsequently washed about 200 mL of water to remove excess surfactant. Finally, the water was replaced with methanol and thereafter the filtrated residue was dried for removing the solvent to give Semiconductor Carbon Nanotubes.

1.5 mg of the obtained Semiconductor Carbon Nanotubes and 1.5 mg of F8BT (poly[(9,9-di-n-octylfluorenyl-2,7-diyl)-alt-(benzo[2,1,3]thiadiazol-4,8-diyl)]; manufactured by Sigma-Aldrich Co. LLC) were added into 15 mL of chloroform. Thereafter, the mixture was stirred with ultrasonic using an ultrasonic homogenizer (VCX-500, manufactured by Tokyo RIKAKIKAI Co., Ltd.) at 250 W output for 30 minutes while the mixture was being cooled with ice to give CNT/Semiconducting polymer complex dispersion liquid A (CNT/semiconducting polymer complex concentration to solvent: 0.1 g/L, purity of

Semiconductor Carbon Nanotubes: 90% by mass) and CNT/Semiconducting polymer complex dispersion liquid B (CNT/semiconducting polymer complex concentration to solvent: 0.1 g/L, purity of Semiconductor Carbon Nanotubes: 94% by mass). Subsequently, these dispersion liquids were diluted with chloroform to give CNT/semiconducting polymer composite solutions A and B having a CNT composite concentration of 0.625 mg/L.

(Preparation of Tin Oxide Nanocrystalline Forming Solution)

The tin oxide nanocrystalline forming solution was prepared by dissolving SnF₂ (manufactured by Wako Pure Chemical Corporation, mass number 156.71 g, purity 90.0%) at 90° C. in distilled water at a concentration of 5 mM.

### (Preparation of Ethanol Dispersion Liquid of Nano-Tin Oxide Fine Particles)

100 mg of tin oxide (IV) powder (manufactured by Kanto Chemical Co., Inc.: average particle size 15.9 nm to 136.7 nm (D_{BET})) was mixed with 15 mL of ethanol in a 20-mL glass vial and the mixture was irradiated with ultrasonic for 60 minutes using an ultrasonic bath (manufactured by Branson Ultrasonics Corporation (CPX2800H-J). Thereafter, the supernatant part allowed to stand at room temperature for 48 hours was served as the ethanol dispersion liquid of nano-tin oxide fine particles.

(Preparation of Sensor Devices)

### <Sensor Device I>

A substrate of a pair of comb-shaped electrodes (platinum electrode/10 μm line gap/glass substrate) manufactured by Metrohm Dropsense AG was completely immersed in the prepared tin oxide nanocrystalline forming solution so as to be at an inclination of 45° to the liquid surface (top surface). In this case, the electrode surface was oriented downward. The temperature of the tin oxide nanocrystalline forming solution was maintained at 90° C. and a tin oxide film was grown on the electrode substrate for 20 minutes. Subsequently, the electrode substrate was taken out from the tin oxide nanocrystalline forming solution, rinsed in running water, and allowed to stand at room temperature and dried.

25 μL of CNT/semiconducting polymer composite solution A having a CNT concentration of 0.625 mg/L was dropped onto the electrode substrate on which the tin oxide film had been grown so as to cover the entire pair of comb-shaped electrodes using a pipette and the solution was dried under a nitrogen atmosphere at 60° C. for 30 minutes.

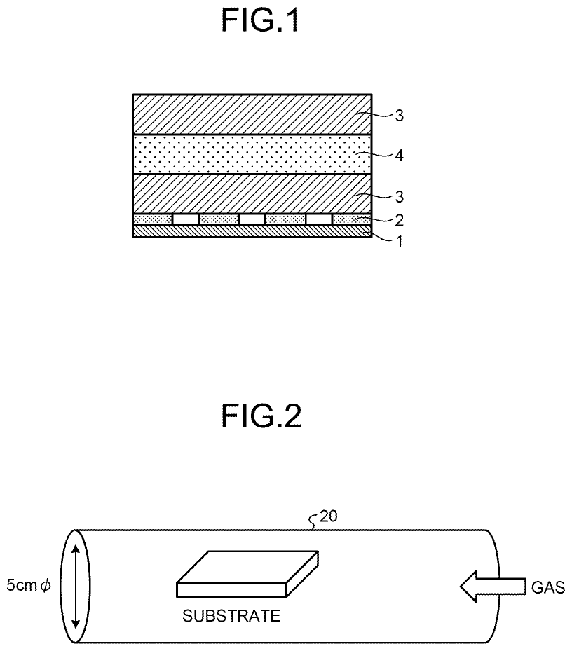

Subsequently, the tin oxide nanocrystalline forming solution was allowed to stand for 20 minutes at 90° C. and thereafter cooled to room temperature to prepare a tin oxide suspension solution in which tin oxide alone was grown in the solution. 25 μL of the tin oxide suspension liquid was dropped so as to cover the entire outermost surface of the pair of comb-shaped electrodes serving as the electrode substrate on which the CNT/semiconducting polymer composite solution A had been applied and dried and dried under a nitrogen atmosphere at 90° C. for 30 minutes to prepare Sensor Device I. A schematic view of the prepared sensor device is illustrated in FIG. 1. In Sensor Device I, a pair of comb-shaped platinum electrodes 2 having a line gap of 10 μm on a glass substrate 1 is provided, a nanostructured tin oxide layer 3 is formed on the platinum electrodes 2, a CNT/semiconducting polymer composite layer 4 is formed on the tin oxide layer 3, and a nanostructured tin oxide layer 4 is further formed on the CNT/semiconducting polymer composite layer 3.

<Sensor Device II>

A substrate of a pair of comb-shaped electrodes (gold electrode/10 μm line gap/glass substrate) manufactured by Metrohm Dropsense AG was completely immersed in the prepared tin oxide nanocrystalline forming solution so as to be at an inclination of 45° to the liquid surface (top surface). In this case, the electrode surface was oriented downward. The temperature of the tin oxide nanocrystalline forming solution was maintained at 90° C. and a tin oxide film was grown on the electrode substrate for 2 hours. Subsequently, the electrode substrate was taken out from the tin oxide nanocrystalline forming solution, rinsed in running water, and allowed to stand at room temperature and dried.

Subsequently, 25 μL of CNT/semiconducting polymer composite solution B having a CNT concentration of 0.625 mg/L was dropped onto the electrode substrate on which the tin oxide film had been grown so as to cover the entire pair of comb-shaped electrodes using a pipette and dried under a nitrogen atmosphere at 60° C. for 30 minutes.

Thereafter, the electrode substrate was completely immersed again in the prepared tin oxide nanocrystalline forming solution so as to be at an inclination of 45° to the liquid surface (top surface). In this case, the electrode surface was oriented downward. The temperature of the tin oxide nanocrystalline forming solution was maintained at 90° C. and a tin oxide film was grown on the electrode substrate for 30 minutes. Subsequently, the electrode substrate was taken out from the tin oxide nanocrystalline forming solution, rinsed in running water, and allowed to stand at room temperature and dried to prepare Sensor Device II.

<Sensor Device III>

25 μL of CNT/semiconducting polymer composite solution A having a CNT concentration of 0.625 mg/L was dropped onto the electrode substrate of the substrate of a pair of comb-shaped electrodes (gold electrode/10 μm line gap/glass substrate) manufactured by Metrohm Dropsense AG so as to cover the entire pair of comb-shaped electrodes using a pipette and dried under a nitrogen atmosphere at 60° C. for 30 minutes to prepare Sensor Device III.

<Sensor Device IV>

A substrate of a pair of comb-shaped electrodes (gold electrode/10 μm line gap/glass substrate) manufactured by Metrohm Dropsense AG was completely immersed in the prepared tin oxide nanocrystalline forming solution so as to be at an inclination of 45° to the liquid surface (top surface). In this case, the electrode surface was oriented downward. The temperature of the tin oxide nanocrystalline forming solution was maintained at 90° C. and a tin oxide film was grown on the electrode substrate for 6 hours. Subsequently, the electrode substrate was taken out from the tin oxide nanocrystalline forming solution, rinsed in running water, and allowed to stand at room temperature and dried to prepare Sensor Device IV formed of tin oxide alone.

<Sensor Device V>

A substrate of a pair of comb-shaped electrodes (gold electrode/10 μm line gap/glass substrate) manufactured by Metrohm Dropsense AG was placed on a hot plate heated at 120° C. 25 μL of the ethanol dispersion liquid of tin oxide nanoparticles was dropped so as to cover the outermost surface of the entire pair of comb-shaped electrodes serving as the electrode substrate using a pipette and the dispersion liquid was dried under a nitrogen atmosphere at 120° C. for 10 minutes to form a nano-tin oxide film onto the electrode. Thereafter, 25 μL of CNT/semiconducting polymer composite solution B having a CNT concentration of 0.625 mg/L was dropped onto a part of the pair of comb-shaped electrodes on which the nano-tin oxide film had been formed so as to cover the outermost surface of the entire pair of comb-shaped electrodes using a pipette and the dried under a nitrogen atmosphere at 120° C. for 10 minutes to prepare Sensor Device V.

(Measurement)

Using prepared Sensor Devices I to V and a glass tube 20 having a shape illustrated in FIG. 2, the resistance change between the pair of comb-shaped electrodes was measured in a state where each of the sensors are set in the glass tube 20 at room temperature (25° C.) or at 50° C. when each sensor device was exposed to sample gases in which an oxygen concentration was 20% and the concentrations of the target detection gases were prepared to the concentrations listed in Examples described below. The results are listed in Examples 1 to 3 and Comparative Examples 1 and 2.

### Example 1

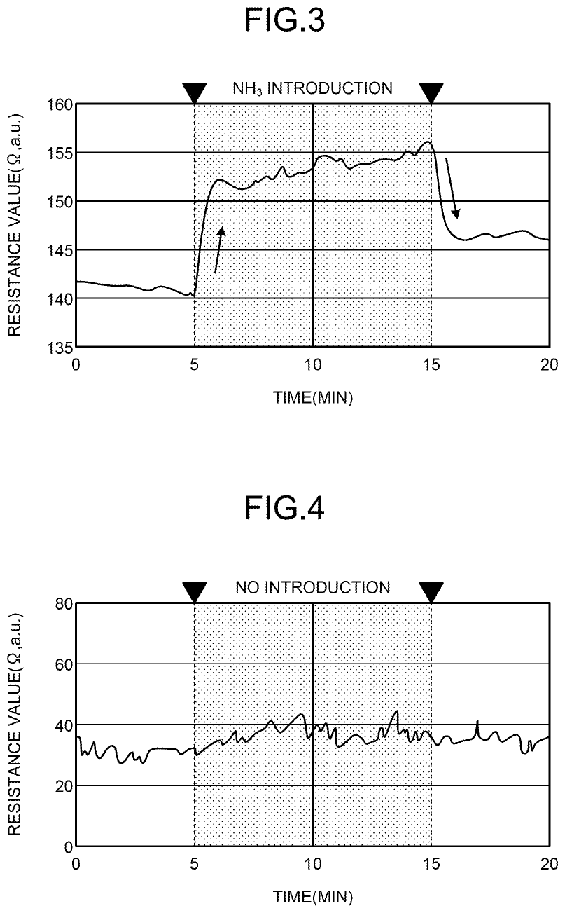

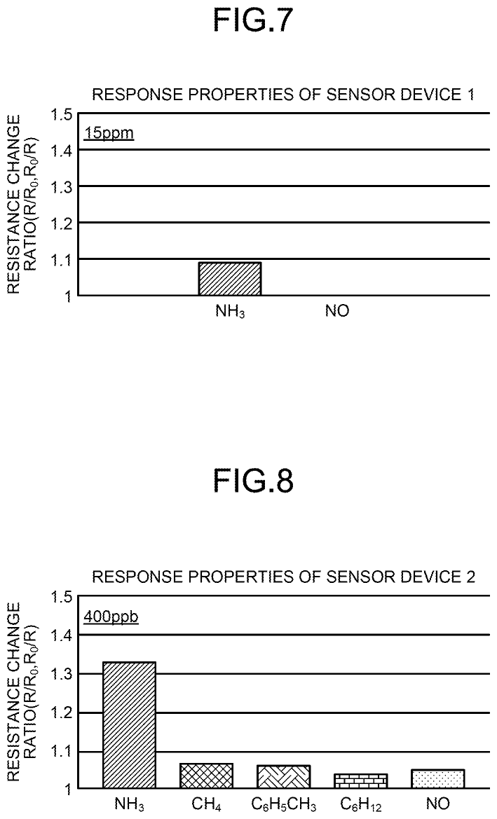

Sensor Device I and Sensor Device III were used to evaluate the response properties to 15 ppm ammonia (NH₃) and nitric oxide (NO) at room temperature (25° C.). Sensor Device I in Example 1 is a sensor device in which the semiconductor purity of the CNTs is 90% by mass, F8BT is used as the semiconducting polymer in the CNT/semiconducting polymer composite, and tin oxide is used as the n-type semiconductor. The results of Example 1 (Sensor Device I) are illustrated in FIG. 3, FIG. 4, and FIG. 7.

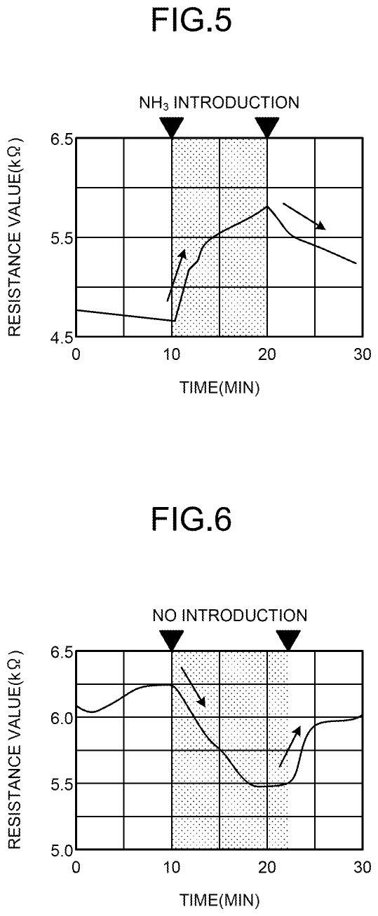

FIG. 3 illustrates the result of exposing Sensor Device I to 15 ppm ammonia gas. The resistance value between the pair of comb-shaped electrodes increased as ammonia gas was introduced and the resistance value returned to the original state when the ammonia gas supply was stopped. Consequently, a clear response property to ammonia gas was confirmed. Compositing the Semiconductor Carbon Nanotubes having a purity of the Semiconductor Carbon Nanotubes of 90% by mass and tin oxide serving as the n-type semiconductor resulted in observing a clear increase in the response speed as compared to the result of a sensor device illustrated in Comparative Example 1 (FIG. 5), in which the film of the CNT/semiconducting polymer composite alone was formed on the pair of comb-shaped electrodes.

FIG. 4 illustrates the results of exposing Sensor Device I to 15 ppm nitric oxide. No change in resistance was observed when nitric oxide was introduced and only noise was observed, resulting in indicating no response properties.

In order to compare the difference in detection intensity between FIG. 3 and FIG. 4, the magnitude of the change between an initial resistance value and a resistance value when Sensor Device I was exposed to the gas was represented by a resistance change ratio (In the case where the initial resistance value was determined to be R₀ and the resistance value after exposure to the gas was determined to be R, Resistance change ratio=R₀/R or R/R₀. In the case of Resistance change ratio=1, no change was observed and thus no detection of the gas was observed). FIG. 7 illustrates the result in which the magnitude of the resistance change ratio was evaluated as the detection ability of the device material to each gas. It can be clearly seen that the resistance change was indicated to ammonia, but not to nitric oxide when Sensor Device I was exposed to nitric oxide.

### Example 2

Sensor Device II was used to evaluate the response properties to 400 ppb ammonia (NH₃), methane (CH₄), toluene (C₆H₅CH₃), cyclohexane (CH₁₂), and nitric oxide (NO) at room temperature (50° C.). Sensor Device II in Example 2 is a sensor device in which the semiconductor purity of the CNTs is 94% by mass, F8BT is used as the semiconducting polymer in the CNT/semiconducting polymer composite, and tin oxide is used as the n-type semiconductor.

The compared results of the detection ability for each gas are illustrated in FIG. 8.

Sensor Device II indicated a resistance change ratio of 1.3 or more for ammonia, but 1.1 or less for other gases. Therefore, selective detection characteristics were observed to ammonia gas among various gases.

### Example 3

Sensor Device V was used to evaluate the response properties to 1 ppm ammonia (NH₃), methane (CH₄), toluene (C₆H₅CH₃), cyclohexane (CH₁₂), and nitric oxide (NO) at room temperature (25° C.). Sensor Device V in Example 3 is a sensor device in which the semiconductor purity of the CNTs is 94% by mass, F8BT is used as the semiconducting polymer in the CNT/semiconducting polymer composite, and nano-tin oxide fine particles are used as the n-type semiconductor.

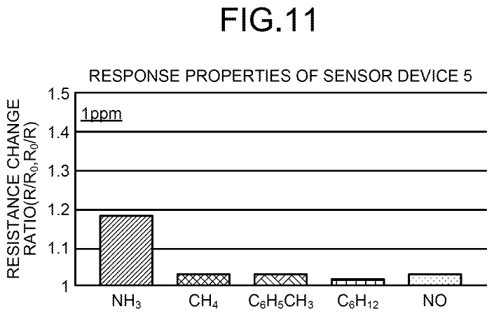

The compared results of the detection ability for each gas are illustrated in FIG. 11.

Sensor Device V indicated a resistance change ratio of 1.15 or more for ammonia but 1.05 or less for other gases. Therefore, selective detection characteristics were observed to ammonia gas among various gases.

### Comparison Example 1

Sensor Device III was used to evaluate the response properties to 15 ppm ammonia (NH₃) and nitric oxide (NO) at room temperature (25° C.). Sensor Device III in is a sensor device in which the n-type semiconductor is not used, the semiconductor purity of the CNTs is 90% by mass, and F8BT is used as the semiconducting polymer in the CNT/semiconducting polymer composite.

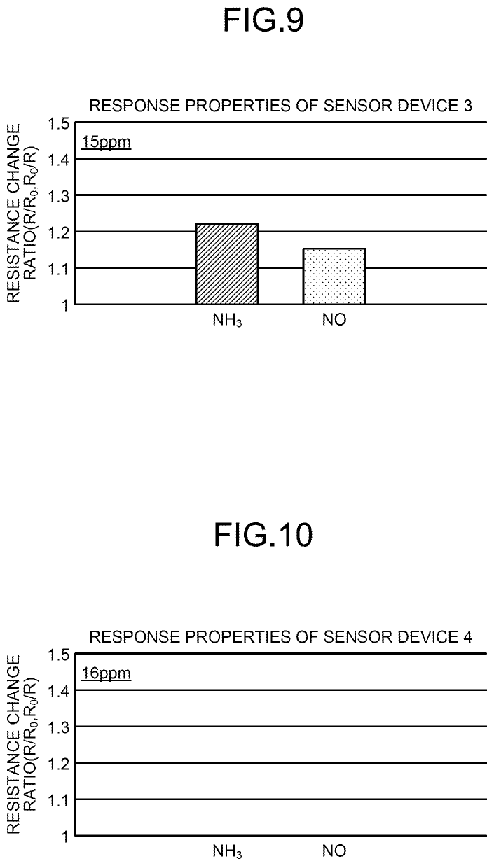

Results are illustrated in FIG. 5, FIG. 6, and FIG. 9.

Similar to Example 1, the response properties to ammonia gas and nitric oxide were measured. FIG. 5 illustrates the results of exposing Sensor Device III to 15 ppm ammonia gas and the resistance value between the pair of comb-shaped electrodes increased with the introduction of ammonia gas, resulting in indicating response properties.

FIG. 6 illustrates the results of exposing Sensor Device III to 15 ppm nitric oxide and the resistance value decreased after nitric oxide was introduced, resulting in indicating the response properties to the gas.

The detection ability of the device materials to the gases is as illustrated in FIG. 9. Sensor Device III indicated difference in sensitivity to the gases but the difference was not as clear as the difference indicated in Example 1.

### Comparison Example 2

Sensor Device IV was used to evaluate the response properties to 16 ppm ammonia (NH₃) and nitric oxide (NO) at room temperature (50° C.)

Results are listed in FIG. 10.

Sensor Device IV did not indicate resistance change to any of the gases and thus tin oxide alone, serving as the n-type semiconductor, was not able to detect the gases in a low-temperature region.

### REFERENCE SIGNS LIST

1 Substrate
2 Electrodes
3 n-Type semiconductor
4 Semiconductor CNT/Semiconducting polymer composite
20 Glass tube

1. An electronic device material, comprising:
carbon nanotubes having a purity of Semiconductor Carbon Nanotubes of 80% by mass or more; and
a n-type semiconductor.

2. The electronic device material according to claim 1, wherein the carbon nanotubes are a carbon nanotube composite with a polymer attached to at least a part of surfaces of the carbon nanotubes.

3. The electronic device material according to claim 2, wherein the polymer is a semiconducting polymer.

4. The electronic device material according to claim 1, wherein the n-type semiconductor has a nanostructure.

5. The electronic device material according to claim 1, wherein the n-type semiconductor is an oxide semiconductor.

6. The electronic device material according to claim 1, wherein the electronic device material is a gas-sensitive element.

7. An electronic device comprising the electronic device material according to claim 1.

8. A sensor device comprising the electronic device material according to claim 1.

9. A gas sensor comprising the sensor device according to claim 8.
